(19) United States
(12) Patent Application Publication
(10) Pub. No.: US 2026/0173269 A1
(43) Pub. Date: Jun. 18, 2026

(54) DEVICES AND SYSTEMS FOR IMMERSION COOLING

(71) Applicant: SK Hynix NAND Product Solutions Corp. (dba Solidigm), Rancho Cordova, CA (US)

(72) Inventors: Justin Boldrini, El Dorado Hills, CA (US); Timothy Rothman, El Dorado, CA (US); Jason Brand, Placerville, CA (US)

(21) Appl. No.: 18/985,977

(22) Filed: Dec. 18, 2024

(51) Int. Cl. H05K 1/14; H05K 3/46

(52) U.S. Cl. CPC H05K 1/142; H05K 3/4691

(57) ABSTRACT

In accordance with some embodiments of the present disclosure, a device includes a first printed circuit board (PCB) including a first major plane and a connector configured to connect to a slot, a second PCB including a second major plane, and a rigid-flex circuit coupling the first PCB to the second PCB at respective distal ends of the PCBs. The device further includes at least one interconnection to communicate signals between the first PCB and the second PCB. The rigid-flex circuit is foldable to orient the device into one of a first form factor or a second form factor. In the first form factor, the first major plane and the second major plane are coplanar, whereas in the second form factor, the first major plane and the second major plane are parallel. The device is configured to be unenclosed such that the device is capable of being immersion cooled.

### TECHNICAL FIELD

The present disclosure is directed to devices and systems including thereof, which are to be immersion cooled in cooling liquids while being unenclosed, and capable of at least two form factors.

### SUMMARY

In accordance with the present disclosure, devices (e.g., a solid-state drive (SSD) devices) and systems including thereof are provided for immersion cooling in cooling liquids (e.g., water, other non-electrolytic liquids, etc.) while being unenclosed. The devices (e.g., SSD) are foldable and may be immersion cooled in at least two form factors. At least one of the form factors is formed by folding the device (e.g., SSD) to reduce the cooling liquid volume (i.e., air space), and subsequently, the energy needed to cool the same components (e.g., same memory units, memory controllers, etc.) as an unfolded device. For example, the reduction in cooling liquid volume (i.e., air space) reduces the energy consumed for keeping the cooling liquid at a certain temperature.

In accordance with the present disclosure, a device includes a first printed circuit board (PCB) including a first major plane and a connector configured to connect to a slot, a second PCB including a second major plane, and a rigid-flex circuit coupling the first PCB to the second PCB at respective distal ends of the first PCB and the second PCB. The device further includes at least one interconnection to communicate signals between the first PCB and the second PCB. The rigid-flex circuit is foldable to orient the device into one of a first form factor or a second form factor. In the first form factor, the first major plane and the second major plane are coplanar, whereas, in the second form factor, the first major plane and the second major plane are parallel. The device is configured to be unenclosed such that the device is capable of being immersion cooled.

In some embodiments, the first and the second form factors include respective enterprise and datacenter standard form factors (EDSFFs).

In some embodiments, the first form factor is of an E1.L form factor.

In some embodiments, the second form factor is of an E1.S form factor.

In some embodiments, respective widths of the first form factor and the second form factor are identical.

In some embodiments, a length of the second form factor is two times a length of the first form factor.

In some embodiments, a length of the second form factor is N times a length of the first form factor, where N is an integer.

In some embodiments, the device is capable of being immersion cooled using a non-electrolytic cooling liquid.

In accordance with the present disclosure, a system includes a first printed circuit board (PCB) including a first major plane and a connector configured to connect to a slot, a second PCB including a second major plane, and a rigid-flex circuit coupling the first PCB to the second PCB at respective distal ends of the first PCB and the second PCB. The system further includes at least one interconnection to communicate signals between the first PCB and the second PCB. The rigid-flex circuit is foldable to orient the device into one of a first form factor or a second form factor. In the first form factor, the first major plane and the second major plane are coplanar, whereas in the second form factor, the first major plane and the second major plane are parallel. The system is configured to be unenclosed such that the system is capable of being immersion cooled. The system further includes a third PCB including the slot, and the connector of the first PCB is connected to the slot.

In some embodiments, the first and the second form factors include respective enterprise and datacenter standard form factors (EDSFFs).

In some embodiments, the first form factor is of an E1.L form factor.

In some embodiments, the second form factor is of an E1.S form factor.

In some embodiments, respective widths of the first form factor and the second form factor are identical.

In some embodiments, a length of the second form factor is two times a length of the first form factor.

In some embodiments, a length of the second form factor is N times a length of the first form factor, where N is an integer.

In some embodiments, the system is capable of being immersion cooled using a non-electrolytic cooling liquid.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in some embodiments” appearing herein describe various embodiments and implementations, and do not necessarily all refer to the same one or more embodiment. However, they are also not necessarily mutually exclusive.

FIG. 1 shows a plan view diagram of an unfolded device, in accordance with some embodiments of the present disclosure;

FIG. 2 shows an isometric view diagram of the unfolded device of FIG. 1 immersed in cooling liquid, in accordance with some embodiments of the present disclosure;

FIGS. 3A-C show diagrams of a top view, a side view, and an isometric view, respectively, of a folded device, in accordance with some embodiments of the present disclosure; and

FIG. 4 shows an isometric view diagram of the folded device of FIGS. 3A-3C immersed in cooling liquid, in accordance with some embodiments of the present disclosure.

### DETAILED DESCRIPTION

In accordance with the present disclosure, devices and systems are provided for a foldable device (e.g., SSD) which is configured to be immersion cooled in cooling liquids (e.g., water, other non-electrolytic liquids, etc.) while being unenclosed. The same device may be immersion cooled in at least two different form factors by including rigid-flex circuit (e.g., a flexible PCB) between two or more PCBs. When the rigid-flex circuits are unflexed, the device forms a first form factor. The rigid-flex circuits may be flexed (e.g., folded), enabling the device to form other form factors.

Storage devices (e.g., SSDs) are often expensive to cool and take up large physical spaces. For example, in the context of datacenters, a large amount of energy and space is consumed when cooling devices (e.g., storage devices, server systems, network switches, other hardware, etc.) by air. Using air to cool devices is an inefficient but widely used method for cooling devices due to the technical simplicity, wide availability, easy implementation, and low material costs. For example, in datacenter air cooling systems, air may be drawn from a “cold aisle” of air in front of the rack holding rows of devices, such that the drawn air passes over each row of devices, and then exhausted into the “hot aisle” of air. The drawn air gets hotter as it passes each row of devices, resulting in a large device temperature difference between the devices at the front and back of the row. Furthermore, temperature variances may also occur vertically within a rack, with lower devices consuming cooler airflow from floor tiles. In contrast, cooling liquids (e.g., water, other non-electrolytic liquids, etc.) are more efficient and consistent (e.g., less variation in temperature distribution) mediums for cooling storage devices, albeit typically consuming more energy. One of the reasons for the higher energy consumption by cooling liquids (i.e., compared to air cooling) comes from energy spent in holding the cooling liquid at a particular temperature (i.e., a temperature which is suitable for cooling the devices. Consequently, lowering the cooling liquid volume (i.e., air space) required by the devices may reduce the energy consumption, as a smaller volume of cooling liquid needs to be held at a particular temperature. This may be achieved by increasing the device density so that the same components of a device (e.g., same memory units, memory controllers, etc.) can be cooled with a smaller volume of cooling liquid.

In one approach to increase device density for immersion purposes, two or more PCBs may be held together by a daughterboard so they can be spaced closely together, minimizing the volume. A daughterboard may be a PCB that plugs into and extends the circuitry of another PCB. However, an extra socket is used by the daughterboard and may result in more lane margin being consumed. Lane margining is a way of defining signal integrity (e.g., signal noise) by measuring signal eye width (i.e., time) and signal height (i.e., voltage). Consequently, using daughterboards may increase signal noise and reduce the available lane margin. In some embodiments, many platforms may not have sufficient lane margin available for this approach as the industry adopts stricter standards to achieve higher data transfer rates.

In another approach to densifying devices, rigid-flex circuits may be used within the device between two or more PCBs. In this approach, the rigid-flex circuits can be flexed (e.g., folded) to provide more storage density. Advantageously, the same device may be immersion cooled in at least two different form factors by flexing (e.g., folding) or unflexing (e.g., not folding) the rigid-flex circuit.

Foldable devices may offer advantages over unfolded devices by using less physical space (i.e., volume) and less energy for cooling for the same components (e.g., same memory units, memory controllers, etc.) as an unfolded device of the same type. Additionally, for immersion applications, certain device form factors (e.g., E1.L, E1.S), typically do not require an enclosure, further reducing volume and heat loss.

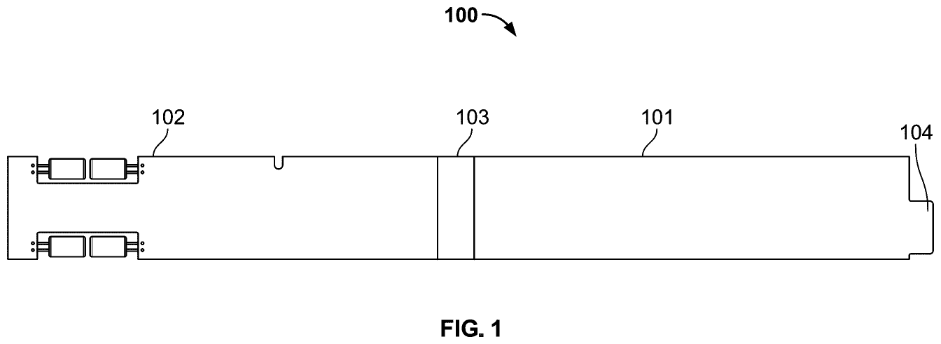

The subject matter of this disclosure is further discussed with reference to FIGS. 1-4.

FIG. 1 shows a plan view diagram of a device (e.g., SSD) 100 that includes a first PCB 101, a second PCB 102, and a rigid-flex circuit 103. In some embodiments, the first and second PCBs, 101 and 102, respectively, may include components such as capacitors, resistors, inductors, diodes, transistors, central processing units (CPUs), memory units (e.g., NAND, DRAM), and controllers (e.g., memory controller). A first end of the first PCB 101 is attached to a first end of the rigid-flex circuit 103. A second end of rigid-flex circuit 103 is further attached to a first end of the second PCB 102. There is at least one interconnection between the first PCB 101, the second PCB 102, and the rigid-flex circuit 103, such that the first PCB 101 is communicatively coupled to the second PCB 102 via the rigid-flex circuit 103. A second end of the first PCB 101 includes a connector 104 which, in some embodiments, may be connected to a slot on a third PCB. In embodiments where the first PCB 101 is connected via connector 104 to a slot on a third PCB, the first PCB 101 is communicatively coupled to the third PCB. The major planes of the first PCB 101, the second PCB 102, and the rigid-flex circuit 103 are co-planar (i.e., the rigid-flex circuit 103 is in an unflexed state) and lined up. In some embodiments, the device 100 may include more than one rigid-flex circuit (such as circuit 103) and more than two PCBs (such as PCBs 101 and 102). In such embodiments, similar to FIG. 1, the major planes of all the rigid-flex circuits and PCBs may be co-planar and lined up.

In some embodiments, the first PCB 101 and the second PCB 102 may have the same width, but slightly different lengths due to the connector 104 in the first PCB 101. In some embodiments, the device 100 may be of an E1.L form factor, any suitable enterprise and datacenter standard form factor (EDSFF), or any other suitable form factor, when in an unfolded state. In some embodiments, the connector 104 may be an EDSFF connector.

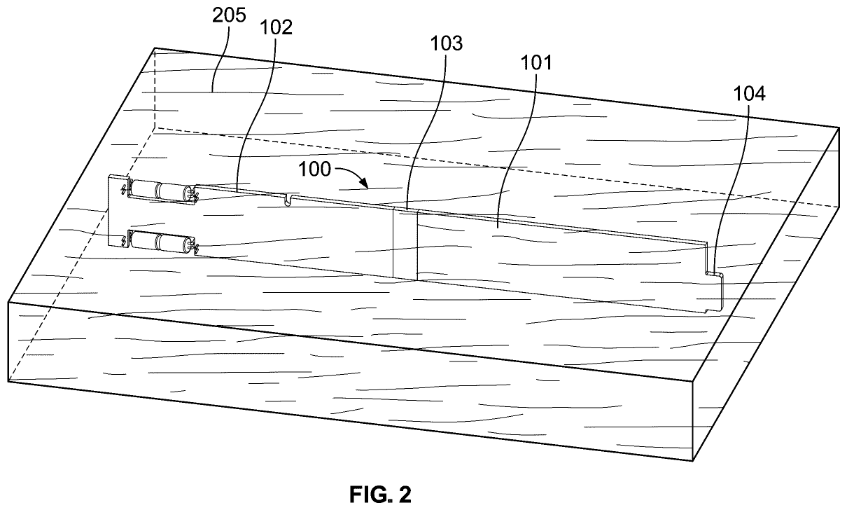

FIG. 2 shows an isometric view diagram of the device 100 (similar to device 100 in FIG. 1) immersed in a cooling liquid 205. When devices are in operation (i.e., currents are flowing within the device), heating naturally occurs due to electrical resistance within the device. If the device 100 becomes hotter than the surrounding cooling liquid 205, heat starts flowing from the device 100 to the cooling liquid 205 until an equilibrium in temperatures is reached. In some embodiments, device 100 is unenclosed and completely immersed in the cooling liquid 205. Being unenclosed enables the device to be in direct contact with the cooling liquid 205, and may increase the efficiency of cooling. While FIG. 2 shows only one device 100 immersed in cooling liquid 205, in some embodiments, two or more devices may be immersed together. In some embodiments, device 100 may include more than two PCBs and more than one rigid-flex circuit. In some embodiments, the cooling liquid 205 may be a non-electrolytic liquid such as purified water, a mixture of water and another compound (e.g., ethylene glycol, propylene glycol, etc.), a mineral oil, or a dielectric liquid.

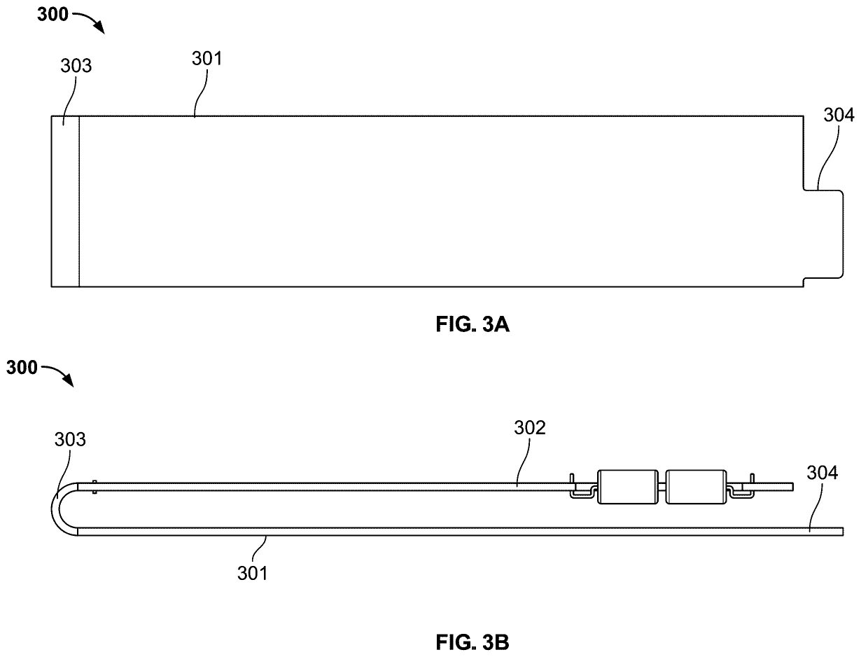

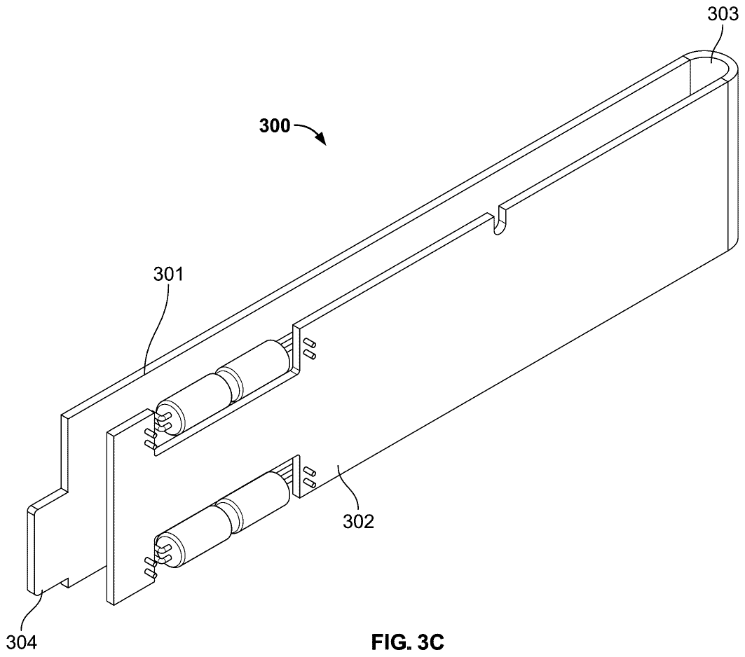

FIGS. 3A-C show diagrams of a top view, a side view, and an isometric view, respectively, of a device (e.g., SSD) 300. The device 300 includes a first PCB 301, a second PCB 302, and a rigid-flex circuit 303. In some embodiments, the first and second PCBs, 301 and 302, respectively, may include components such as capacitors, resistors, inductors, diodes, transistors, central processing units (CPUs), memory units (e.g., NAND, DRAM), and controllers (e.g., memory controller). A first end of the first PCB 301 is attached to a first end of a rigid-flex circuit 303. A second end of the rigid-flex circuit 303 is further attached to a first end of the second PCB 302. There is at least one interconnection between the first PCB 301, the second PCB 302, and the rigid-flex circuit 303, such that the first PCB 301 is communicatively coupled to the second PCB 302 via the rigid-flex circuit 303. A second end of the first PCB 301 includes a connector 304 which, in some embodiments, may be connected to a slot on a third PCB. In embodiments where the first PCB 101 is connected via connector 104 to a slot on a third PCB, the first PCB 101 is communicatively coupled to the third PCB. The major planes of the first PCB 301 and the second PCB 302 are parallel to each other, and the rigid-flex circuit 303 is in a flexed/folded state. In some embodiments, the device 300 may include more than one rigid-flex circuit (such as circuit 303) and more than two PCBs (such as first PCB 301 and second PCB 302). In such embodiments, similar to FIG. 1, the major planes of all the PCBs are parallel to each other, and the rigid-flex circuits are in a folded/flexed state.

In some embodiments, the first PCB 301 and the second PCB 302 may have the same width, but slightly different lengths due to the connector 304 in the second PCB 302. In some embodiments, the device 300 may be of an E1.S form factor, any suitable EDSFF, or any other suitable form factor, when in a folded state. The width of the folded form factor (e.g., E1.S) may be the same as the unfolded form factor (e.g., E1.L), but the lengths may be different. The unfolded form factor (e.g., E1.L) may be about twice the length of the folded form factor (e.g., E1.S). In some embodiments, the connector 304 may be an EDSFF connector.

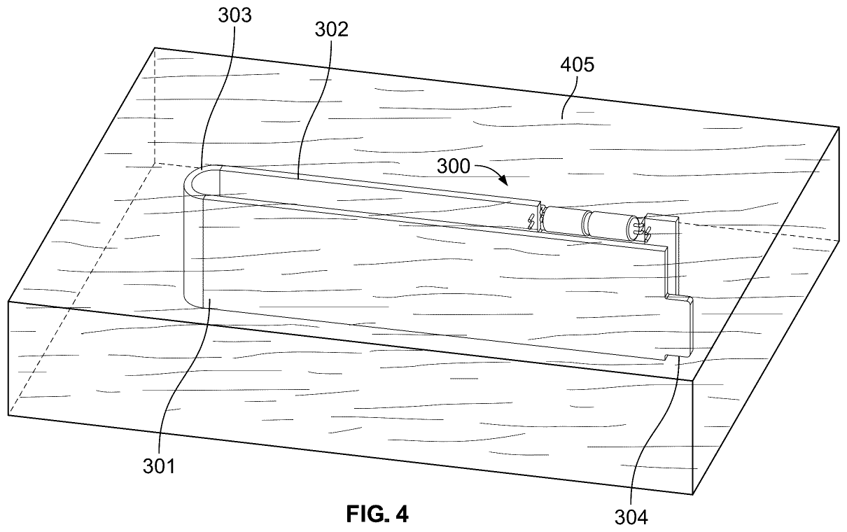

FIG. 4 shows an isometric view diagram of the device 300 (similar to the device 300 in FIGS. 3A-C) immersed in a cooling liquid 405. When devices are in operation (i.e., currents are flowing within the device), heating naturally occurs due to electrical resistance within the device. If the device 300 becomes hotter than the surrounding cooling liquid 405, heat starts flowing from the device 300 to the cooling liquid 405 until an equilibrium in temperatures is reached. In some embodiments, device 100 is unenclosed and completely immersed in the cooling liquid 405. Being unenclosed enables the device to be in direct contact with the cooling liquid 405, and may increase the efficiency of cooling. While FIG. 4 shows only one device 300 immersed in cooling liquid 405, in some embodiments, two or more devices may be immersed together. In some embodiments, device 100 may include more than two PCBs and more than one rigid-flex circuit. In some embodiments, the cooling liquid 405 may be a non-electrolytic liquid such as purified water, a mixture of water and another compound (e.g., ethylene glycol, propylene glycol, etc.), a mineral oil, or a dielectric liquid.

In some embodiments, the rigid-flex circuit (e.g., 103, 303) may be flexible (e.g., foldable). In some embodiments, a rigid-flex circuit may provide higher stability, lighter weight and smaller volume.

In some embodiments, a device may include more than one rigid-flex circuit and be configured to fold multiple times. For example, the device may include N (e.g., 2) rigid-flex circuits, N+1 (e.g., 3) PCBs, and folded N times (e.g., 2 times) at the rigid-flex circuits to render the N+1 (e.g., 3) PCBs parallel to each other. In the case of storage devices (e.g., SSDs), more PCBs may provide more storage. This may enable further conservation of physical space at data centers and reduction in energy consumption. For example, energy consumption is reduced by reducing the amount of cooling liquid and subsequently cooling energy (i.e., the power used to keep the cooling liquid at a certain temperature) required for a larger device density.

The term “end” when referring to an end of a PCB or a circuit means “distal end” unless expressly specified otherwise.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A device comprising:
a first printed circuit board (PCB) comprising a first major plane and comprising a connector configured to connect to a slot;
a second PCB comprising a second major plane; and
a rigid-flex circuit coupling the first PCB to the second PCB at respective distal ends of the first PCB and the second PCB, and comprising at least one interconnection to communicate signals between the first PCB and the second PCB, wherein:
the rigid-flex circuit is foldable to orient the device into one of a first form factor or a second form factor,
in the first form factor, the first major plane and the second major plane are coplanar,
in the second form factor, the first major plane and the second major plane are parallel, and
the device is configured to be unenclosed such that the device is capable of being immersion cooled.

2. The device of claim 1, wherein the first and the second form factors comprise respective enterprise and datacenter standard form factors (EDSFFs).

3. The device of claim 1, wherein the first form factor is of an E1.L form factor.

4. The device of claim 1, wherein the second form factor is of an E1.S form factor.

5. The device of claim 1, wherein respective widths of the first form factor and the second form factor are identical.

6. The device of claim 1, wherein a length of the second form factor is two times a length of the first form factor.

7. The device of claim 1, wherein a length of the second form factor is N times a length of the first form factor, wherein N is an integer.

8. The device of claim 1, wherein the device is capable of being immersion cooled using a non-electrolytic cooling liquid.

9. A system comprising:
a first printed circuit board (PCB) comprising a first major plane and comprising a connector configured to connect to a slot;
a second PCB comprising a second major plane;
a rigid-flex circuit coupling the first PCB to the second PCB at respective distal ends of the first PCB and the second PCB, and comprising at least one interconnection to communicate signals between the first PCB and the second PCB, wherein:
the rigid-flex circuit is foldable to orient the system into one of a first form factor or a second form factor,
in the first form factor, the first major plane and the second major plane are coplanar,
in the second form factor, the first major plane and the second major plane are parallel, and
the system is configured to be unenclosed such that the system is capable of being immersion cooled; and
a third PCB comprising the slot, wherein the connector of the first PCB is connected to the slot.

10. The system of claim 9, wherein the first and the second form factors comprise respective enterprise and datacenter standard form factors (EDSFFs).

11. The system of claim 9, wherein the first form factor is of an E1.L form factor.

12. The system of claim 9, wherein the second form factor is of an E1.S form factor.

13. The system of claim 9, wherein respective widths of the first form factor and the second form factor are identical.

14. The system of claim 9, wherein a length of the second form factor is two times a length of the first form factor.

15. The system of claim 9, wherein a length of the second form factor is N times a length of the first form factor, wherein N is an integer.

16. The system of claim 9, wherein the system is capable of being immersion cooled using a non-electrolytic cooling liquid.
